(19) United States
(12) Patent Application Publication
(10) Pub. No.: US 2011/0284934 A1
(43) Pub. Date: Nov. 24, 2011

(54) SEMICONDUCTOR DEVICE AND METHOD OF FABRICATING THE SAME

(75) Inventors: Zhijiong Luo, Poughkeepsie, NY (US); Huilong Zhu, Poughkeepsie, NY (US); Haizhou Yin, Poughkeepsie, NY (US)

(73) Assignee: Institute of Microelectronics, Chinese Academy of Sciences, Beijing (CN)

(21) Appl. No.: 12/997,766

(22) PCT Filed: Sep. 16, 2010
(86) PCT No.: PCT/CN10/01418

§ 371 Date: Dec. 13, 2010

(30) Foreign Application Priority Data
Apr. 9, 2010 (CN) 201010145090.5

(51) Int. Cl. H01L 29/772; H01L 21/336

(52) U.S. Cl. 257/288; 438/299; 438/285; 257/E29.242; 257/E21.409

(57) ABSTRACT

There are provided a semiconductor device and a method of fabricating the same. The semiconductor device comprises: a semiconductor substrate of a first conductive type; a gate formed on the semiconductor substrate; and a heavily doped region of the first conductive type and a heavily doped region of a second conductive type formed respectively in the semiconductor substrate at either side of the gate, wherein the heavily doped region of the second conductive type is separated from the channel region under the gate and partially separated from the semiconductor substrate by a dielectric layer. By means of this semiconductor device, it is possible to provide excellent switching behavior.

### FIELD OF INVENTION

The present invention generally relates to the semiconductor field, and more particularly, to a semiconductor device in which the sub-threshold swing is improved and a method of fabricating the same.

### DESCRIPTION OF PRIOR ART

The sub-threshold state is an important operation mode for Metal Oxide Semiconductor Field Effect Transistors (MOSFET's). It is an operation mode where a gate voltage Vgs of a MOSFET is lower than its threshold voltage VT and thus no conductive channel occurs. In this state, there is still a small amount of current flowing through the device, which is referred to as a sub-threshold current. Though the sub-threshold current is small, it can be well controlled by the gate voltage. Thus, it is advantageous to apply MOSFET's in the sub-threshold state to low voltage and low power consumption applications, especially, to Large Scale Integrated Circuits (LSICs) such as logic switches and memories.

A sub-threshold swing, also referred to as S factor, is an important parameter for a MOSFET which operates in the sub-threshold state and is used as a logic switch. It is defined as S=dVgs/d(log 10 Id) in a unit of [mV/decade]. S is equal to, in magnitude, an increment ΔVgs of the gate voltage required to increase a drain current Id by one decade, that is, a rising slope of the Id-Vgs curve. The value of the S factor is dependent on the device structure and the temperature. At room temperature, a theoretic minimum of the'S factor is 60 mV/decade.

However, the S factor will not be decreased with the scaling of MOSFET devices, which limit the extent to which the threshold voltage and hence the supply voltage for the MOSFET devices can be reduced.

In view of this, there is a need for a novel semiconductor device and a method for fabricating the same, to achieve steeper switching behavior (for example, S<60 mV/decade at room temperature).

### SUMMARY OF THE INVENTION

It is an object of the present invention to provide a semiconductor device and a method of fabricating the same, whereby it is possible to improve the sub-threshold swing (S), especially, to reduce the S value to be lower than 60 mV/decade at room temperature, and thus to provide better switching behavior.

According to an aspect of the present invention, there is provided a semiconductor device, comprising: a semiconductor substrate of a first conductive type; a gate formed on the semiconductor substrate; and a heavily doped region of the first conductive type and a heavily doped region of a second conductive type formed respectively in the semiconductor substrate at either side of the gate, wherein an end portion of the heavily doped region of the second conductive type at the gate side is separated from the semiconductor substrate by a dielectric layer.

Preferably, the first conductive type may be P type and the second conductive type may be N type; or alternatively, the first conductive type may be N type and the second conductive type may be P type.

Preferably, the gate may comprise: a gate insulation layer formed on the semiconductor substrate; and a heavily doped gate body of the second conductive type and formed on the gate insulation layer.

Preferably, the heavily doped region of the second conductive type may comprise a metal material close to the second conductive type.

Preferably, the dielectric layer may comprise an oxide or nitride film, and may have a thickness smaller than 50 Å.

According to another aspect of the present invention, there is provided a method of fabricating a semiconductor device, comprising: providing a semiconductor substrate of a first conductive type; forming a gate on the semiconductor substrate; forming a heavily doped region of the first conductive type in the semiconductor substrate at a first side of the gate; and forming a heavily doped region of a second conductive type in the semiconductor substrate at a second side, which is opposite to the first side, of the gate, wherein before the heavily doped region of the second conductive type is formed, a dielectric layer is formed at an end portion of the heavily doped region of the second conductive type to be formed at the gate side.

Preferably, the first conductive type may be P type and the second conductive type may be N type; or alternatively, the first conductive type may be N type and the second conductive type may be P type.

Preferably, the step of forming the gate may comprise: forming a gate insulation layer on the semiconductor substrate; and forming a heavily doped gate body of the second conductive type on the gate insulation layer.

Preferably, the step of forming the heavily doped region of the first conductive type may comprise: forming an overlying layer on the semiconductor substrate at the second side of the gate; forming the heavily doped region of the first conductive type at the first side of the gate; and removing the overlying layer.

Preferably, the steps of forming the dielectric layer and of forming the heavily doped region of the second conductive type may comprise: forming a protective layer on the semiconductor substrate at the first side of the gate; selectively etching the semiconductor substrate at the second side of the gate to form a recess; forming the dielectric layer in the recess at the gate side; forming the heavily doped region of the second conductive type in the recess; and removing the protective layer.

Preferably, the dielectric layer may comprise an oxide or nitride film, and may have a thickness smaller than 50 Å.

Preferably, the step of forming the heavily doped region of the second conductive type in the recess may comprise: epitaxially growing Si or SiGe on the semiconductor substrate in the recess, and the Si or SiGe being heavily doped to have the second conductive type.

Preferably, the step of forming the heavily doped region of the second conductive type in the recess may comprise: depositing Si on the semiconductor substrate in the recess, and the Si being heavily doped to have the second conductive type.

Preferably, the step of forming the heavily doped region of the second conductive type in the recess may comprise: depositing a metal material close to the second conductive type on the semiconductor substrate in the recess.

The semiconductor device according to the embodiments of the present invention operates based on the quantum tunneling effect, and thus has a very high switching speed. Thus, it is possible to achieve S<60 mV/decade at room temperature.

### BRIEF DESCRIPTION OF THE DRAWINGS

The above and other objects, features and advantages of the present invention will be more apparent by describing embodiments thereof in detail with reference to the attached drawings, wherein:

FIGS. 1-6 show intermediate structures in respective steps during a flow of fabricating a semiconductor device according to an embodiment of the invention;

FIG. 7 is a structural diagram showing a semiconductor device according to an embodiment of the invention; and

FIGS. 8(a) and (b) show the operating principle of the semiconductor device according to an embodiment of the invention.

### DETAILED DESCRIPTION OF PREFERRED EMBODIMENTS

Hereinafter, the present invention is described with reference to embodiments shown in the attached drawings. However, it is to be understood that those descriptions are only provided for illustrative purpose, rather than limiting the present invention. Further, in the following, descriptions of known structures and techniques are omitted so as not to obscure the concept of the present invention.

In the drawings, various structural diagrams and sectional views of semiconductor devices according to embodiments of the present invention are shown. However, they are not drawn to scale, and some features may be enlarged while some features may be omitted for clarity. Shapes, sizes and relative positions of respective regions and layers shown in the drawings are only illustrative, and deviations therefrom may occur due to manufacture tolerances and technical limits. Those skilled in the art can also devise regions/layers of different shapes, sizes and relative locations as desired.

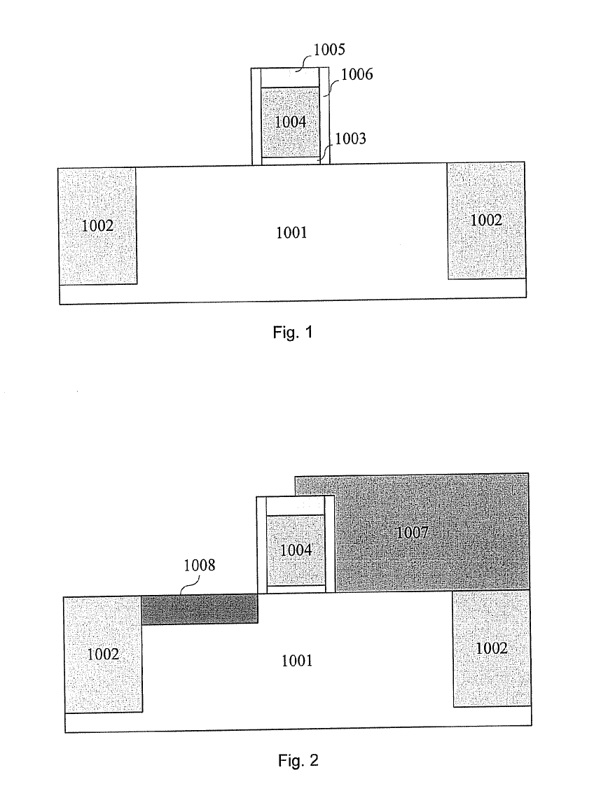

FIGS. 1-6 show intermediate structures in respective steps during a flow of fabricating a semiconductor device according to an embodiment of the invention. In the following, the steps as well as the resulting semiconductor device according to the embodiment of the invention are described in detail with reference to those drawings.

First, as shown in FIG. 1, a semiconductor substrate 1001 of a first conductive type (here, P type for example) is provided, such as a Si substrate. Further, a gate stack for a transistor is formed on the semiconductor substrate 1001. Specifically, the gate stack may comprise a gate insulation layer 1003, a gate body 1004, and a hard mask layer 1005, as well as spacers 1006 formed at both sides thereof, which are formed in sequence. For example, the gate insulation layer 1003 may comprise SiO₂, the gate body 1004 may comprise poly-silicon, and the hard mask layer 1005 and the spacers 1006 may comprise nitride such as SiNₓ. Preferably, the gate body 1004 may comprise heavily doped poly-silicon of a second conductive type (here, N type for example).

Those skilled in the art can conceive various ways to fabricate such a gate stack on the semiconductor substrate. Since the gate stack is not directly relevant to the subject matter of the present invention, the detailed descriptions thereof are omitted here.

Here, it is to be noted that the term of “heavily doped” in this specification means a higher doping concentration than that of the semiconductor substrate 1001. For example, a material is considered as being heavily doped if it is doped in a concentration higher than 10²⁰ cm⁻³.

Preferably, Shallow Trench Isolations (STIs) 1002 may be further formed in the semiconductor substrate 1001 to improve the isolation between devices.

Then, as shown in FIG. 2, a overlying layer 1007 is formed on the semiconductor substrate 1001 with the gate stack formed thereon. The overlying layer 1007 is patterned so that it only covers the region at one side of the gate stack (for example, the right side as shown in the drawing). For example, the overlying layer 1007 may be formed of photoresist, and may be subjected to exposure and developing so as to only remain at the right side of the gate stack. Alternatively, the overlying layer 1007 may be a separate layer formed of other materials, which then can be patterned by photolithography so that it only remains at the right side of the gate stack. In FIG. 2, it is shown that a portion of the overlying layer 1007 is left on the top of the gate stack, but this is not necessary. It is also possible for the overlying layer 1007 to cover the region at the right side of the gate stack.

After the region at the right side of the gate stack is covered by the overlying layer 1007, a heavily doped region 1008 of the first conductive type (P⁺) is formed at the other side of the gate stack (the left side as shown in the drawing). For example, this may be achieved by ion implantation (boron, for example). Since the region of right side is covered by the overlying layer 1007, it will not be impacted by the ion implantation.

After the region 1008 is formed, the overlying layer 1007 is removed.

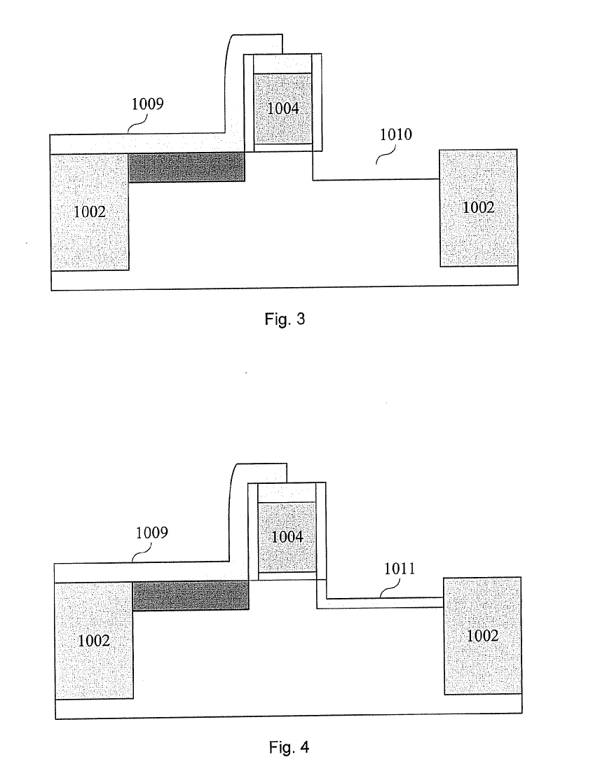

Next, as shown in FIG. 3, a protective layer 1009 is formed on the semiconductor substrate. The protective layer 1009 is patterned so that it remains on the region at the left side of the gate stack. For example, the protective layer 1009 may be formed of nitride (SiNₓ). In FIG. 3, it is shown that a portion of the protective layer 1009 is left on the top of the gate stack, but this is not necessary. It is also possible for the protective layer 1009 to cover the region at the left side of the gate stack.

In this state, at the right side of the gate stack, the semiconductor substrate 1001 may be selectively etched to from a recess 1010. For example, an etchant which selectively etch the semiconductor substrate (for example, Si) and the oxide and nitride (such as STI 1002, the hard mask layer 1005, the spacers 1006 and the protective layer 1009) may be used to perform the etching. Alternatively, the etching may be performed by Reactive Ion Etching (RIE).

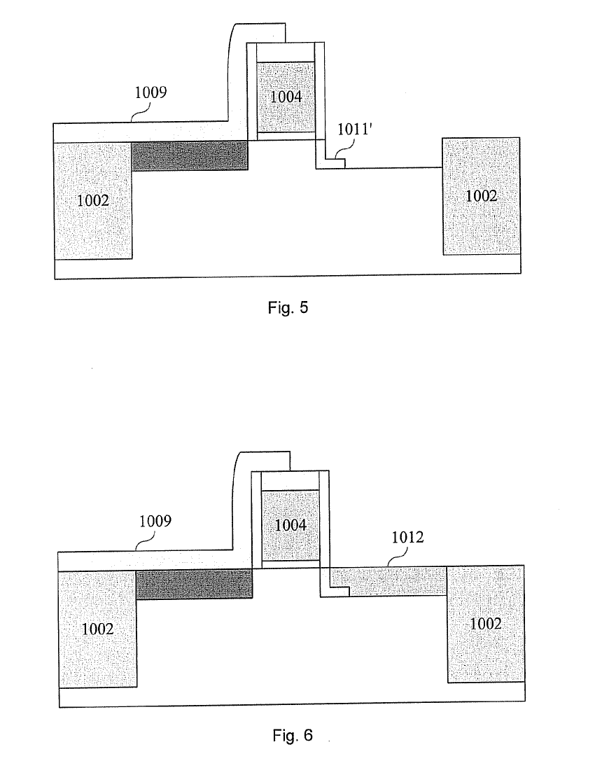

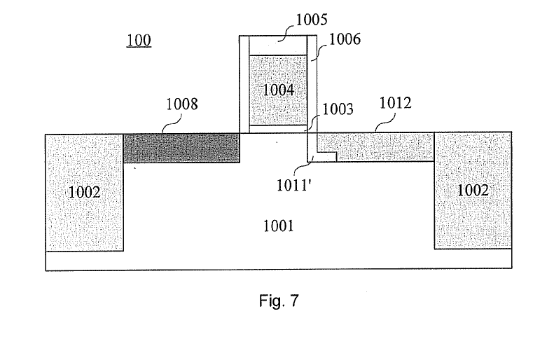

Subsequently, as shown in FIG. 4, a very thin dielectric layer 1011 is formed on the semiconductor substrate in the recess 1011. Preferably, the dielectric layer 1011 has a thickness smaller than 50 Å. The dielectric layer 1011 may be an oxide film, for example, formed by thermal oxidation of the semiconductor substrate, or by deposition. Alternatively, the dielectric layer 1011 may be a nitride film, for example, formed by deposition. Next, as shown in FIG. 5, the dielectric layer 1011 is patterned to remove the portion thereof located at the side farther away from the gate stack and thus expose the semiconductor substrate 1001. Due to the remaining portion of the dielectric layer 1011′, it is possible to ensure a steep distribution profile of the doping concentration for the N⁺ junction (referring to 1012 as shown in FIGS. 6 and 7) to be formed later.

Then, as shown in FIG. 6, a heavily doped region 1012 of the second conductive type (in this case, N type) is formed in the recess 1010. For example, the region 1012 may be formed by epitaxial growth of Si or SiGe on the semiconductor substrate 1001, with the grown Si or SiGe being heavily doped to have the second conductive type (in this case, N type). The doping may be achieved by ion implantation after the epitaxial growth, or by doping in situ during the epitaxial growth. Alternatively, a layer of Si may be deposited, and is heavily doped to have the second conductive type (in this case, N type), for example, by ion implantation or doping in situ.

Alternatively, the region 1012 may be formed by depositing a metal close to the second conductive type (here, N type). The reference to “a metal close to the second conductive type” refers to a metal whose Fermi level is close to that of the heavily doped semiconductor material of the second conductive type. For example, in the case where the second conductive type is N type, the metal may comprise Ni, Ti and the like.

Next, as shown in FIG. 7, the protective layer 1009 is removed. Thus, the semiconductor device according to the embodiment of the invention is obtained. Specifically, the semiconductor device may comprise: the semiconductor substrate 1001 of the first conductive type; the gate (1003, 1004, 1005, and 1006) formed on the semiconductor substrate; and the heavily doped region 1008 of the first conductive type and the heavily doped region 1012 of the second conductive type which are formed respectively at either side of the gate in the semiconductor substrate (for example, the region 1008 constitutes the source, and the region 1012 constitutes the drain), wherein an end portion of the heavily doped region 1012 of the second conductive type at the gate side is spaced from the semiconductor substrate by the dielectric layer 1011′.

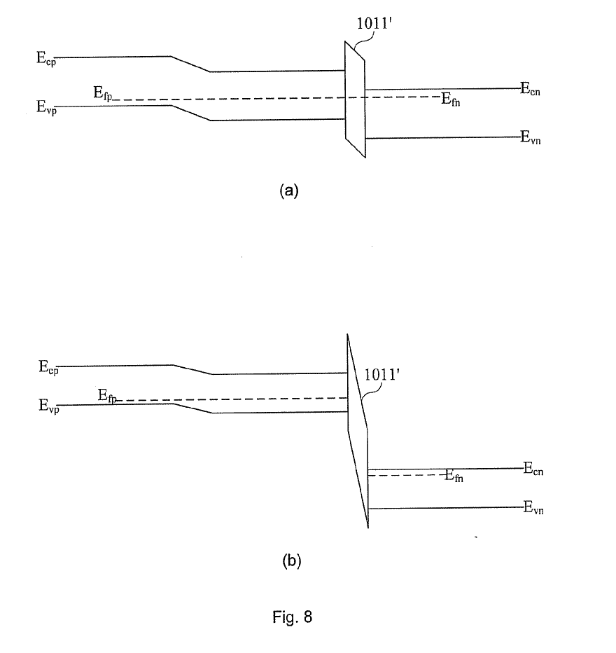

The semiconductor device operates mainly based on the quantum tunneling effect. FIG. 8 is a diagram showing energy bands of the semiconductor device, wherein portion (a) shows the energy band configuration when there is no gate bias, and portion (b) shows the energy band configuration when there is a negative gate bias. Here, E_{cp} indicates the conduction band for the P⁺ junction, Eᵥₚ indicates the valence band for the P⁺ junction, E_{cn} indicates the conduction band for the N⁺ junction, Eᵥₙ indicates the valence band for the N⁺ junction, E_{fp} indicates the Fermi level for the P⁺ junction, and E_{fn} indicates the Fermi level for the N⁺ junction. It can be seen that electrons will pass through the barrier which becomes thinner due to the quantum tunneling effect at the negative gate bias, resulting in a tunneling current. The tunneling current can be modulated by the gate voltage, and thus the semiconductor device behaviors as a three-terminal device.

In this semiconductor device, whether it is turned on or off is based on the control of the inter-band tunneling at the negative gate bias. Since there is very short time for the interaction between the electrons and the barrier, the transit time of this device is shorter than that of conventional MOS devices. Therefore, this device has a very fast switching speed, and thus it is possible to achieve S<60 mV/decade at room temperature.

Here, the dielectric layer 1011′ is provided at the end portion of the region 1012 at the gate side. Thus, it is possible to ensure a steep distribution profile of the doping concentration in the direction of the PN junction in this region. Such steep distribution profile of the doping concentration will facilitate the formation of a thin barrier, which in turn facilitates the tunneling current.

Here, it is to be noted that the overlying layer 1007 and the protective layer 1009, which are provided in the above description to achieve separate processes at the left side and right side of the gate respectively, are not necessary for the present invention. There are various ways apparent for those skilled in the art to carry out separate processes on the regions of the semiconductor substrate at the left and right sides of the gate respectively.

In the above description, the embodiments are described in the case where the first conductive type is P type and the second conductive type is N type. However, the present invention is not limited thereto. Alternatively, the first conductive type may be N type, and the second conductive type may be P type.

Further, in the above description, the heavily doped region 1008 of the first conductive type is formed before the heavily doped region 1012 of the second conductive type is formed. However, the sequence of the formations of those regions is not limited thereto. For example, the heavily doped region 1012 of the second conductive type may be formed before the heavily doped region 1008 of the first conductive type is formed.

In the above description, details of pattering and etching of the respective layers are not provided. It is to be understood by those skilled in the art that various means in the prior art may be utilized to form the layers and regions in desired shapes. Further, to achieve the same structure, those skilled in the art may devise different methods than those described above.

The present invention is described above with reference to the embodiments thereof. However, those embodiments are provided only for illustrative purpose, rather than limiting the present invention. The scope of the invention is defined by the attached claims as well as equivalents thereof. Those skilled in the art can make various alternations and modifications without departing from the scope of the invention, which all fall into the scope of the invention.

1. A semiconductor device, comprising:
a semiconductor substrate of a first conductive type;
a gate formed on the semiconductor substrate; and
a heavily doped region of the first conductive type and a heavily doped region of a second conductive type formed respectively in the semiconductor substrate at either side of the gate,
wherein the heavily doped region of the second conductive type is separated from the channel region under the gate and partially separated from the semiconductor substrate both by a dielectric layer.

2. The semiconductor device according to claim 1, wherein the first conductive type is P type and the second conductive type is N type, or the first conductive type is N type and the second conductive type is P type.

3. The semiconductor device according to claim 1, wherein the gate comprises:
a gate insulation layer formed on the semiconductor substrate; and
a heavily doped gate body of the second conductive type formed on the gate insulation layer.

4. The semiconductor device according claim 1, wherein the heavily doped region of the second conductive type comprises a metal material close to the second conductive type.

5. The semiconductor device according to claim 1, wherein the dielectric layer comprises an oxide or nitride film, and has a thickness smaller than 50 Å.

6. A method of fabricating a semiconductor device (100), comprising:
providing a semiconductor substrate of a first conductive type;
forming a gate on the semiconductor substrate;
forming a heavily doped region of the first conductive type in the semiconductor substrate at a first side of the gate; and
forming a heavily doped region of a second conductive type in the semiconductor substrate at a second side, which is opposite to the first side, of the gate,
wherein before the heavily doped region of the second conductive type is formed, a dielectric layer is formed to separate the channel region under the gate and to partially separate the semiconductor substrate both from the heavily doped region of the second conductive type.

7. The method according to claim 6, wherein the first conductive type is P type and the second conductive type is N type, or the first conductive type is N type and the second conductive type is P type.

8. The method according to claim 6, wherein the step of forming a gate comprises:
forming a gate insulation layer on the semiconductor substrate; and
forming a heavily doped gate body of the second conductive type on the gate insulation layer.

9. The method according to claim 6, wherein the step of forming a heavily doped region of the first conductive type comprises:
forming an overlying layer on the semiconductor substrate at the second side of the gate;
forming the heavily doped region of the first conductive type at the first side of the gate; and
removing the overlying layer.

10. The method according to claim 6, wherein the steps of forming a dielectric layer and forming the heavily doped region of the second conductive type comprise:
forming a protective layer on the semiconductor substrate at the first side of the gate;
selectively etching the semiconductor substrate at the second side of the gate to form a recess;
forming the dielectric layer in the recess at the gate side;
forming the heavily doped region of the second conductive type in the recess; and
removing the protective layer.

11. The method according to claim 10, wherein the dielectric layer comprises an oxide or nitride film, and has a thickness smaller than 50 Å.

12. The method according to claim 10, wherein the step of forming the heavily doped region of the second conductive type in the recess comprises:
epitaxially growing Si or SiGe on the semiconductor substrate in the recess, and the Si or SiGe being heavily doped to have the second conductive type.

13. The method according to claim 10, wherein the step of forming the heavily doped region of the second conductive type in the recess comprises:
depositing Si on the semiconductor substrate in the recess, and the Si being heavily doped to have the second conductive type.

14. The method according to claim 10, wherein the step of forming the heavily doped region of the second conductive type in the recess comprises:
depositing a metal material close to the second conductive type on the semiconductor substrate in the recess.
